(19) United States
(12) Patent Application Publication
(10) Pub. No.: US 2003/0123235 A1
(43) Pub. Date: Jul. 3, 2003

(54) Wireless local area network card

(76) Inventors: Chih-Min Hsu, Taipei (TW); Ten-Long Dang, Judung Jen (TW)

Correspondence Address: RABIN & BERDO, P.C., Suite 500, 1101 14th Street N.W., Washington, DC, 20005, US

(21) Appl. No.: 10/330,320

(22) Filed: Dec. 30, 2002

(30) Foreign Application Priority Data
Dec. 31, 2001 (TW) 90224699

(51) Int. Cl. H05K 5/00; H05K 5/04; H05K 5/06

(52) U.S. Cl. 361/752

(57) ABSTRACT

A wireless local area network card includes a main body, and an antenna. The main body includes a circuit board which has a first side that can be inserted into an equipment, and a second side. The antenna is pivotally mounted on the second side of the main body, and is exposed outward from the main body, so that the antenna may be pivoted to a have a desired inclined angle. Thus, the antenna may be freely pivoted to a desired angle to facilitate the wireless local area network card emitting and receiving the wireless signals, so that the wireless signals may be adjusted to the optimum condition.

### BACKGROUND OF THE INVENTION

1. Field of the Invention

The present invention relates to a wireless local area network card, and more particularly to a wireless local area network (WLAN) card having an angle adjustable antenna, wherein the antenna may be freely pivoted to a desired angle to facilitate the wireless local area network card emitting and receiving the wireless signals, so that the wireless signals may be adjusted to the optimum condition.

2. Description of the Related Art

A conventional wireless local area network card in accordance with the prior art shown in FIG. 8 may be used in a notebook computer 32, and includes a circuit 30 board 30 inserted into the notebook computer 32, and an antenna 31 mounted on one side of the circuit board 30 and protruded outward from the notebook computer 32, so as to emit and receive the wireless signals. However, the antenna 31 is hidden in the housing of the wireless local area network card, and the wireless local area network card is communicated by the microwave that is propagated in a linear manner, so that the microwave transfer is easily blocked or interrupted by foreign objects or obstacles. As a result, the transfer effect and quality of emitting and receiving the wireless signals are greatly reduced.

### SUMMARY OF THE INVENTION

The present invention has arisen to mitigate and/or obviate the disadvantage of the conventional wireless local area network card.

The objective of the present invention is to provide a wireless local area network card which has an angle-adjustable antenna.

Another objective of the present invention is to provide a wireless local area network card, wherein the antenna may be freely pivoted to a desired angle to facilitate the wireless local area network card emitting and receiving the wireless signals, so that the wireless signals may be adjusted to the optimum condition.

A further objective of the present invention is to provide a wireless local area network card, wherein the antenna may be freely pivoted to a desired angle, so that the transfer of the wireless signals will not be blocked or interrupted by foreign objects or obstacles, thereby enhancing the transfer effect and quality of emitting and receiving the wireless signals.

In accordance with the present invention, there is provided a wireless local area network card, comprising:

a main body, including a circuit board, the circuit board having a first side that may be inserted into an equipment, and a second side in parallel with the first side; and

an antenna, pivotally mounted on the second side of the main body, and exposed outward from the main body, so that the antenna may be pivoted to a have a desired inclined angle.

Further benefits and advantages of the present invention will become apparent after a careful reading of the detailed description with appropriate reference to the accompanying drawings.

### BRIEF DESCRIPTION OF THE DRAWINGS

FIG. 1 is an exploded perspective view of a wireless local area network card in accordance with a preferred embodiment of the present invention;

FIG. 2 is a perspective assembly view of a wireless local area network card in accordance with a preferred embodiment of the present invention;

FIG. 3 is a partially cut-away side plan cross-sectional view of the wireless local area network card as shown in FIG. 2;

FIG. 4 is a side plan cross-sectional operational view of the wireless local area network card as shown in FIG. 2;

FIG. 5 is a side plan cross-sectional operational view of the wireless local area network card as shown in FIG. 2;

FIG. 6 is a side plan cross-sectional operational view of the wireless local area network card as shown in FIG. 2;

FIG. 7 is an operational view of the wireless local area network card as shown in FIG. 2; and

FIG. 8 is a side plan cross-sectional view of a conventional wireless local area network card in accordance with the prior art.

### DETAILED DESCRIPTION OF THE INVENTION

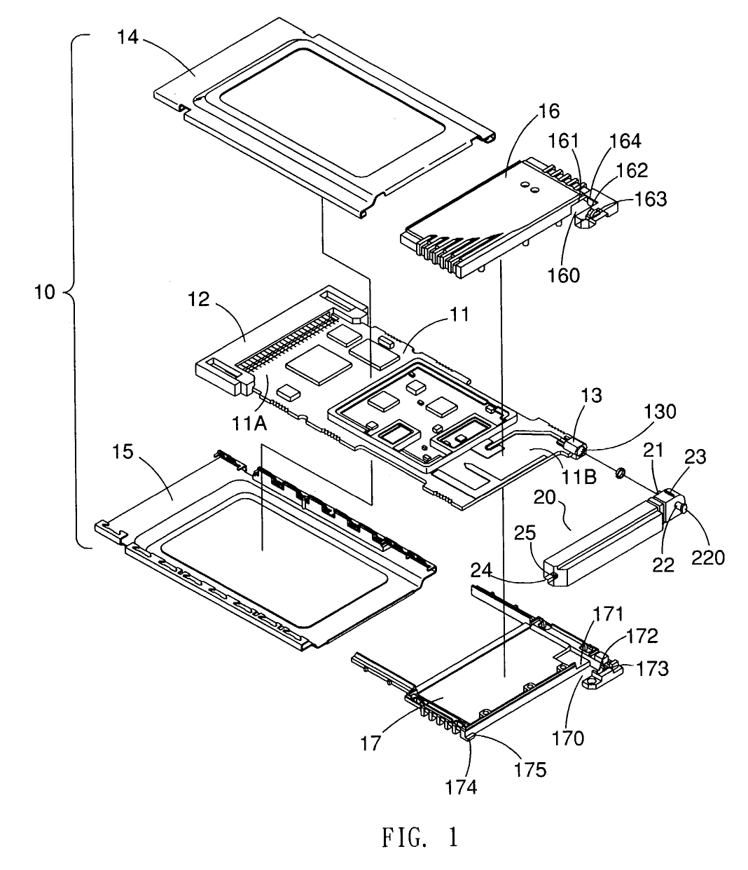

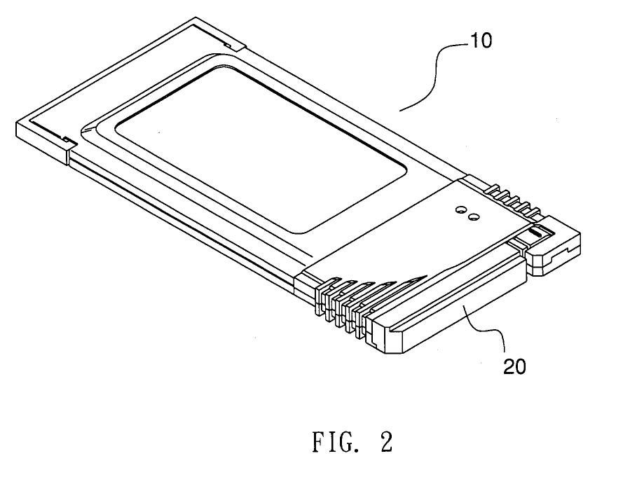

Referring to the drawings and initially to FIGS. 1-3, a wireless local area network (WLAN) card in accordance with a preferred embodiment of the present invention can be inserted into an equipment, such as a notebook computer, and comprises a main body 10, and an antenna 20 pivotally mounted on one side of the main body 10.

In the embodiment, the main body 10 includes a circuit board 11, a front upper cover 14, a front lower cover 15, a rear upper cover 146, and a rear lower cover 17.

The circuit board 11 emits and receives signals, and has a first side 11A that may be inserted into the equipment, and a second side 11B. In the embodiment, the second side 11B is in parallel with the first side 11A. The first side 11A of the circuit board 11 is provided with an insertion terminal 12, so that when the main body 10 is inserted into the equipment to a desired position, the insertion terminal 12 may be electrically connected to the circuit contained in the equipment. The second side 11B of the circuit board 11 is provided with an antenna pivot seat 13 which is formed with a pivot hole 130, for pivoting one end of the antenna 20, thereby forming an connection state.

In the preferred embodiment of the present invention, the circuit design of the circuit board 11 adopts the specification of PCMACIA, so that the main body 10 may be regarded as the PCMACIA card. Thus, the equipment having the insertion slot that support the PCMACIA card can be available for the main body 10 disclosed in the preferred embodiment of the present invention.

The front upper cover 14 and the front lower cover 15 may be combined with each other in a snapping manner, to enclose the circuit board 11, so that only the second side 11B of the circuit board 11 is exposed.

The rear upper cover 16 and the rear lower cover 17 may be combined with each other in a snapping manner, to enclose the second side 11B of the circuit board 11.

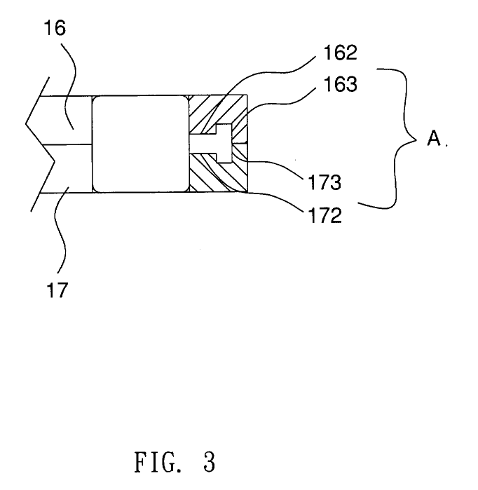

The rear upper cover 16 has one end formed with a slot 160 opposite to the antenna pivot seat 13 of the second side 11B of the circuit board 11. As shown in FIGS. 1 and 3, the slot 160 of the rear upper cover 16 has a first side formed with a breach 161, and a second side formed with a semi-circular recess 162 aligning with the breach 161. The semi-circular recess 162 has one side formed with a semi-circular insertion recess 163 having a diameter greater than that of the semi-circular recess 162. The slot 160 of the rear upper cover 16 has a side edge formed with a flange 164 for locking and positioning the antenna 20 when the antenna 20 is disposed at an upright state.

The rear lower cover 17 has first end formed with a slot 170 opposite to the antenna pivot seat 13 of the second side 11B of the circuit board 11. As shown in FIGS. 1 and 3, the slot 170 of the rear lower cover 17 has a first side formed with a breach 171, and a second side formed with a semi-circular recess 172 aligning with the breach 171. The semi-circular recess 172 has one side formed with a semi-circular insertion recess 173 having a diameter greater than that of the semi-circular recess 172. The rear lower cover 17 has second end protruded with a protrusion 174 which has one side protruded with a locking edge 175 for locking and positioning the antenna 20 when the antenna 20 is folded and disposed at a horizontal state.

In such a manner, the front upper cover 14 and the front lower cover 15 may be snapped with each other, and the rear upper cover 16 and the rear lower cover 17 may be snapped with each other, to entirely enclose the circuit board 11, so that only the antenna pivot seat 13 of the second side 11B of the circuit board 11 is exposed outward from the breaches 161 and 171 of the slots 160 and 170. As shown in FIG. 3, the semi-circular recesses 162 and 172 and the semi-circular insertion recesses 163 and 173 may be combined to form a stepwise hole “A”, so that one end of the antenna 20 may be pivotally mounted on the antenna pivot seat 13 of the second side 11B of the circuit board 11, and may be received in the stepwise hole “A”.

The antenna 20 has a first end having a first side provided with a first pivot shaft 21 pivotally mounted in the pivot hole 130 of the antenna pivot seat 13 of the second side 11B of the circuit board 11, and a second side provided with a second pivot shaft 22 pivotally mounted in the stepwise hole “A”. The antenna 20 may be connected to the circuit board 11 by connection of the first pivot shaft 21 of the antenna 20 with the antenna pivot seat 13 of the second side 11B of the circuit board 11. The second pivot shaft 22 of the antenna 20 has a distal end protruded with an enlarged insertion head 220 inserted in the semi-circular insertion recesses 163 and 173 of the rear upper cover 16 and the rear lower cover 17, thereby preventing from detachment of the second pivot shaft 22 of the antenna 20.

The first end of the antenna 20 is provided with a protruding rib 23 that may be locked on the flange 164 of the slot 160 of the rear upper cover 16 when the antenna 20 is disposed at an upright state. The antenna 20 has a second end formed with a cutout 24 which has a bottom edge protruded with a locking rib 25 that may be locked on the locking edge 175 of the rear lower cover 17 when the antenna 20 is folded and disposed at a horizontal state.

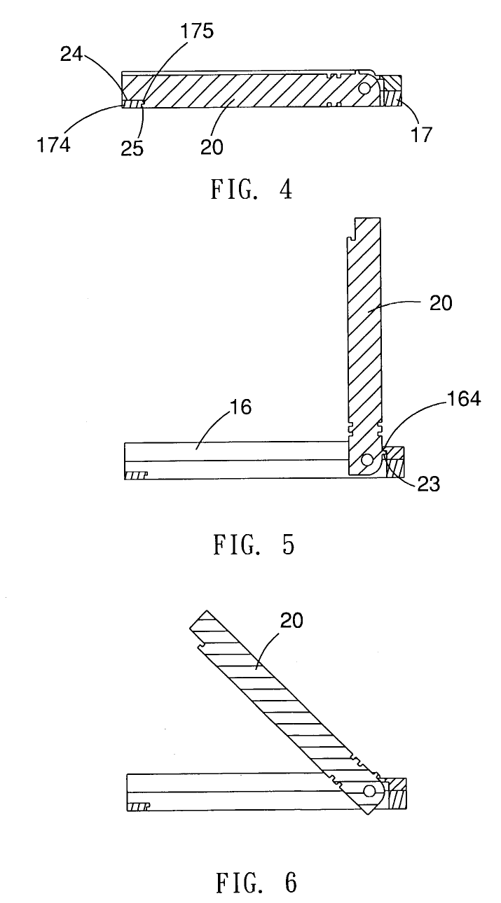

In operation, referring to FIGS. 4-7 with reference to FIGS. 1-3, operation of the wireless local area network (LAN) card in accordance with a preferred embodiment of the present invention is shown and illustrated.

As shown in FIG. 4, when the antenna 20 is folded and disposed at a horizontal state, the protrusion 174 of the rear lower cover 17 is received in the cutout 24 of the antenna 20, and the locking rib 25 of the antenna 20 is locked on the locking edge 175 of the rear lower cover 17, thereby locking and positioning the antenna 20 on the rear lower cover 17.

As shown in FIG. 5, when the antenna 20 is disposed at an upright state, the protruding rib 23 of the antenna 20 is locked on the flange 164 of the slot 160 of the rear upper cover 16, thereby locking and positioning the antenna 20 on the rear upper cover 16.

As shown in FIG. 6, the antenna 20 may be pivoted to have an inclined angle between 0 and 90 degrees according to the requirement.

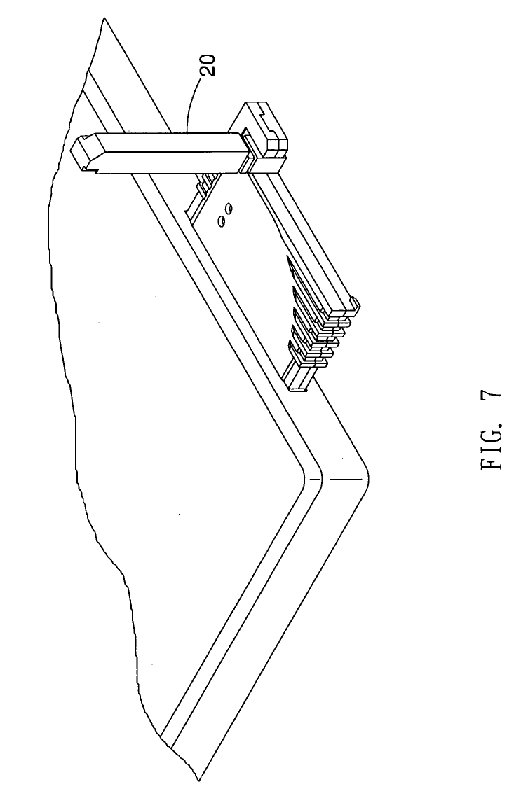

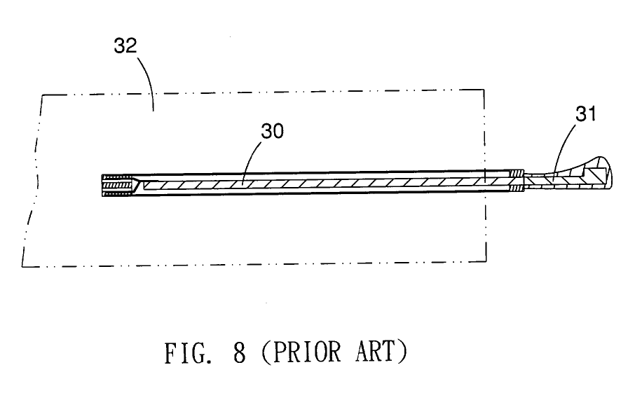

As shown in FIG. 7, the antenna 20 may be pivoted to have an inclined angle between 0 and 90 degrees according to the practical requirement, so that when the wireless local area network (LAN) card is emitting and receiving the signals, the transfer of the signals will not be blocked or interrupted by foreign objects or obstacles, thereby enhancing the transfer effect of emitting and receiving the signals.

Although the invention has been explained in relation to its preferred embodiment as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A wireless local area network card, comprising:
a main body, including a circuit board, the circuit board having a first side that may be inserted into an equipment, and a second side; and
an antenna, pivotally mounted on the second side of the main body, and exposed outward from the main body, so that the antenna can be pivoted to a desired inclined angle.

2. The wireless local area network card in accordance with claim 1, wherein the second side of the circuit board is provided with an antenna pivot seat for pivoting the antenna.

3. The wireless local area network card in accordance with claim 2, wherein the antenna pivot seat is formed with a pivot hole, and the antenna has one end provided with a first pivot shaft pivotally mounted in the pivot hole of the antenna pivot seat of the second side of the circuit board.

4. The wireless local area network card in accordance with claim 1, wherein the first side of the circuit board is provided with an insertion terminal.

5. The wireless local area network card in accordance with claim 1, wherein the main body includes a front upper cover and a front lower cover which may be combined with each other in a snapping manner, to enclose the circuit board, so that only the second side of the circuit board is exposed.

6. The wireless local area network card in accordance with claim 1, wherein the main body includes a rear upper cover and a rear lower cover which can be combined with each other, to enclose the second side of the circuit board.

7. The wireless local area network card in accordance with claim 6, wherein the rear upper cover has one end formed with a slot, the slot of the rear upper cover has a first side formed with a breach, and a second side formed with a semi-circular recess aligning with the breach, the semi-circular recess has one side formed with a semi-circular insertion recess having a diameter greater than that of the semi-circular recess, the rear lower cover has first end formed with a slot, the slot of the rear lower cover has a first side formed with a breach, and a second side formed with a semi-circular recess aligning with the breach, the semi-circular recess has one side formed with a semi-circular insertion recess having a diameter greater than that of the semi-circular recess, the semi-circular recesses and the semi-circular insertion recesses of the rear upper cover and the rear lower cover may be combined to form a stepwise hole, so that one end of the antenna may be received in the stepwise hole.

8. The wireless local area network card in accordance with claim 7, wherein the slot of the rear upper cover has a side edge formed with a flange for locking and positioning the antenna.

9. The wireless local area network card in accordance with claim 7, wherein the rear lower cover has second end protruded with a protrusion which has one side protruded with a locking edge for locking and positioning the antenna when the antenna is folded and disposed at a horizontal state.

10. The wireless local area network card in accordance with claim 7, wherein the antenna has a first end having a first side provided with a first pivot shaft pivotally mounted on the second side of the circuit board, and a second side pivoted with a second pivot shaft pivotally mounted in the stepwise hole.

11. The wireless local area network card in accordance with claim 10, wherein the second pivot shaft of the antenna has a distal end protruded with an enlarged insertion head inserted in the semi-circular insertion recesses of the rear upper cover and the rear lower cover, thereby preventing from detachment of the second pivot shaft of the antenna.

12. The wireless local area network card in accordance with claim 8, wherein the first end of the antenna is provided with a protruding rib that may be locked on the flange of the slot of the rear upper cover when the antenna is disposed at an upright state.

13. The wireless local area network card in accordance with claim 9, wherein the antenna has a second end formed with a cutout which has a bottom edge protruded with a locking rib that may be locked on the locking edge of the rear lower cover when the antenna is folded and disposed at a horizontal state.

14. A wireless local area network card, comprising:
a main body, including a circuit board; and
an antenna, mounted on the main body and exposed outward from the main body.

15. The wireless local area network card in accordance with claim 14, wherein the main body further has a first side that may be inserted into an equipment, and a second side; and
the antenna is pivotally mounted on the second side of the main body, so that the antenna can be pivoted to a desired inclined angle.

16. The wireless local area network card in accordance with claim 15, wherein the first side is opposite to the second side.

17. The wireless local area network card in accordance with claim 14, wherein the antenna has at least a pivot shaft pivotally mounted on the circuit board.

18. The wireless local area network card in accordance with claim 14, wherein the antenna has at least a pivot shaft pivotally mounted on the main body.
